(19) United States
(12) Patent Application Publication
(10) Pub. No.: US 2022/0254875 A1
(43) Pub. Date: Aug. 11, 2022

(54) SEMICONDUCTOR POWER DEVICE TERMINAL STRUCTURE

(71) Applicant: SUZHOU ORIENTAL SEMICONDUCTOR CO., LTD., Jiangsu (CN)

(72) Inventors: Yi GONG, Jiangsu (CN); Lei LIU, Jiangsu (CN); Wei LIU, Jiangsu (CN); Xin WANG, Jiangsu (CN)

(21) Appl. No.: 17/428,151

(22) PCT Filed: Nov. 28, 2019
(86) PCT No.: PCT/CN2019/121675

§ 371 Date: Aug. 3, 2021

(30) Foreign Application Priority Data
Oct. 28, 2019 (CN) 201911030369.6

(51) Int. Cl. H01L 29/06

(52) U.S. Cl. CPC H01L 29/0607; H01L 29/7811

(57) ABSTRACT

Provided are an audio data processing method and apparatus, a device and a storage medium. The method includes: acquiring audio data to be processed and a variable-speed rate of at least one audio frame in the audio data; sequentially using the at least one audio frame as a current audio frame to be processed, and converting the current audio frame to a frequency domain; determining a target phase signal of the current audio frame according to a variable-speed rate of the current audio frame and a variable-speed rate of a previous audio frame; and performing, according to the target phase signal, time domain conversion on the current audio frame converted to the frequency domain to obtain a processed current audio frame.

This application claims priority to Chinese Patent Application No. 201911030369.6 filed with the CNIPA on Oct. 28, 2019, the disclosure of which is incorporated herein by reference in its entirety.

### TECHNICAL FIELD

The present application belongs to the technical field of semiconductor power devices, and in particular, to a terminal structure of a semiconductor power device.

### BACKGROUND

As a third generation power electronic product, a high-voltage semiconductor device such as IGBT and VDMOS has been widely used in the field of power electronics due to high working frequency, fast switching speed and high control efficiency. For example, the high-voltage semiconductor device is widely used in automotive electronics, consumer electronics and industrial control of switching power supply boxes (such as relays, energy-saving lamp electronic ballasts, frequency control of motor speed, high-frequency heating, motor drive, audio apparatuses of household electrical appliances, and switching voltage regulator). The blocking capability of the high-voltage semiconductor device is a very important symbol for measuring the development level. A breakdown voltage may range from 25V to 6500V according to the application. However, since a planar terminal structure is adopted in the semiconductor technology, a junction depth is shallow, and an edge of a junction edge is bent. In this manner, a withstand voltage is reduced, the poor withstand voltage stability is poor, a safe working region of the device is relatively small, and the device is easy to be damaged. Therefore, in order to improve and stabilize the withstand voltage characteristics of the device, besides the cooperation of various parameters in the device, it is more important to properly deal with a PN junction terminated at a surface to improve the electric field distribution at edges of the device, weaken the electric field concentration on the surface, and improve the withstand voltage capability and the stability of the device.

### SUMMARY

The present application provides a terminal structure of a semiconductor power device to improve the withstand voltage capability and the stability of the semiconductor power device.

Embodiments of the present application provide a terminal structure of a semiconductor power device.

The terminal structure of the semiconductor power device includes an n-type epitaxial layer, at least one groove disposed in the n-type epitaxial layer, a first electrode disposed in an upper groove portion and a second electrode disposed at least in a lower groove portion, and a first p-type doped region adjacent to the at least one groove.

The at least one groove each includes the upper groove portion and the lower groove portion.

Every two among the second electrode, the first electrode, and the n-type epitaxial layer are isolated by an insulating dielectric layer.

Optionally, the first p-type doped region is externally connected to a source voltage in the present application.

Optionally, a depth of the first p-type doped region is greater than a depth of the at least one groove, and the first p-type doped region covers and surrounds all or part of the at least one groove in the present application.

Optionally, a thickness of an insulating dielectric layer between the second electrode and the n-type epitaxial layer is greater than or equal to a thickness of an insulating dielectric layer between the first electrode and the n-type epitaxial layer in the present application.

Optionally, the present application further includes a second p-type doped region disposed in the first p-type doped region, and a doping concentration of the second p-type doped region is greater than a doping concentration of the first p-type doped region.

Optionally, a width of the upper groove portion is greater than a width of the lower groove portion in the present application.

Optionally, the second electrode extends upwardly into the upper groove portion in the present application.

Optionally, the second electrode is configured to divide the first electrode into two parts in the upper groove portion in the present application.

Optionally, the present application further includes an insulating layer covering the at least one groove and a metal layer covering the insulating layer.

Optionally, the metal layer is externally connected to a source voltage in the present application.

### BRIEF DESCRIPTION OF DRAWINGS

FIG. 1 is a cross-sectional view of a terminal structure of a semiconductor power device according to a first embodiment of the present application;

FIG. 2 is a cross-sectional view of a terminal structure of a semiconductor power device according to a second embodiment of the present application; and

FIG. 3 is a cross-sectional view of a terminal structure of a semiconductor power device according to a third embodiment of the present application.

### DETAILED DESCRIPTION

The technical solutions of the present application are described hereinafter through embodiments in conjunction with the drawings of embodiments of the present application. The described embodiments are part, not all, of embodiments of the present application.

The terms used in the present application such as “provided”, “comprising” and “including” do not exclude the presence or addition of one or more other components or other combinations. Sizes of figures in the drawings are not representative of the actual size and the drawings are schematic and should not limit the scope of the present application. The listed embodiments in the specification are not intend to limit specific shapes of the regions shown in the drawings, but include obtained shapes, for example, deviations due to manufacturing.

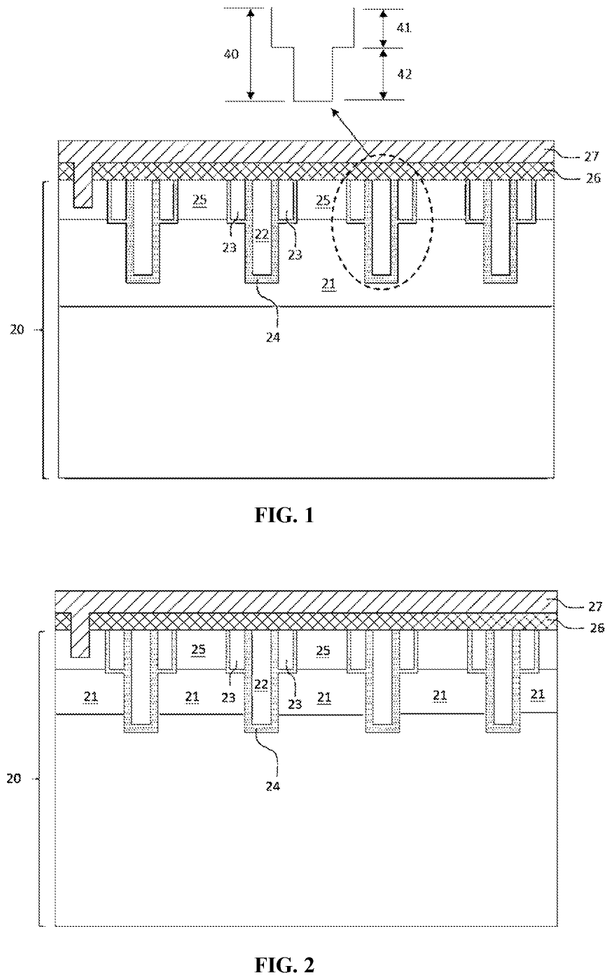

FIG. 1 is a cross-sectional view of a terminal structure of a semiconductor power device according to a first embodiment of the present application. As shown in FIG. 1, the terminal structure of the semiconductor power device provided by the embodiment of the present application includes an n-type epitaxial layer 20 and at least one groove 40 disposed in the n-type epitaxial layer 20. FIG. 1 exemplarily illustrates four grooves 40, and the groove 40 includes an upper groove portion 41 and a lower groove portion 42. For the grooves 40 of the terminal structure of the semiconductor power device shown in FIG. 1, a width of the upper groove portion 41 is greater than a width of the lower groove portion 42.

The terminal structure of the semiconductor power device further includes a first electrode 23 disposed in the upper groove portion 41 and a second electrode 22 disposed at least in the lower groove portion 22. Every two among the second electrode 22, the first electrode 23, and the n-type epitaxial layer 20 are isolated by an insulating dielectric layer 24. The insulating dielectric layer 24 is typically made of silicon oxide, and the first electrode 23 and the second electrode 22 are typically made of polysilicon. Based on selection of the manufacturing process of the semiconductor power device, a thickness of an insulating dielectric layer 24 between the second electrode 22 and the n-type epitaxial layer 20 is greater than or equal to a thickness of an insulating dielectric layer 24 between the first electrode 23 and the n-type epitaxial layer 20. Exemplarily, when the insulating dielectric layer 24 is an oxide layer such as silicon oxide, a thickness of an oxide layer between the second electrode 22 and the n-type epitaxial layer 20 is greater than or equal to a thickness of an oxide layer between the first electrode 23 and the n-type epitaxial layer 20. Optionally, the second electrode 22 may extend upwardly into the upper groove portion 41. When the second electrode 22 extends upwardly into the upper groove portion 41, the first electrode 23 may still be one connected part in the upper groove portion 41, and the first electrode 23 may also be divided in to two parts (as shown in FIG. 1) by the second electrode 22.

The terminal structure of the semiconductor power device further includes a first p-type doped region 21 adjacent to the at least one groove 40, and a depth of the first p-type doped region 21 is greater than a depth of the at least one groove 40. In this case, the first p-type doped region 21 can cover and surround the at least one groove 40. Optionally, the depth of the first p-type doped region 21 may also be equal to or less than the depth of the at least one groove 40 (FIG. 2 is a cross-sectional view of a terminal structure of a semiconductor power device according to a second embodiment of the present application, and in this embodiment, the depth of the first p-type doped region 21 is less than the depth of the at least one groove 40).

The terminal structure of the semiconductor power device further includes a second p-type doped region 25 disposed in the first p-type doped region 21, and a doping concentration of the second p-type doped region 25 is greater than a doping concentration of the first p-type doped region 21. The second p-type doped region 25 is externally connected to a source voltage through a metal layer 27. The first p-type doped region 21 may not be formed with the second p-type doped region 25, and in this case, the first p-type doped region 21 can be externally connected to the source voltage through the metal layer 27 in direct. Based on the selection of the manufacturing process of the semiconductor power device, the second p-type doped region 25 may further be formed with an n-type doped region, and details will not be described in the embodiment of the present application.

A terminal structure of a semiconductor power device of the embodiment of the present application can adjust the longitudinal electric field distribution near the groove, reduce the electric field at the bottom of the groove (that is, at the bottom position of the lower groove portion), and improve the withstand voltage of the semiconductor power device. Meanwhile, a capacitor with a thick oxide layer between the second electrode and the n-type epitaxial layer can fix movable charges in a terminal of the semiconductor power device and improve the reliability of the semiconductor power device.

A terminal structure of a semiconductor power device provided by the present application may further include an insulating layer 26 covering the at least one groove 40 and a metal layer 27 covering the insulating layer 26, and the metal layer 27 is externally connected to the source voltage. In the terminal structure of the semiconductor power device provided by the present application and shown in FIG. 1, both the metal layer 27 and the insulating layer 26 cover the grooves 40 and the n-type epitaxial layer 20. Optionally, the insulating layer and the metal layer may cover only the groove part 40, and in this case, the metal layer may be externally connected to the source voltage or float without being externally connected to the source voltage.

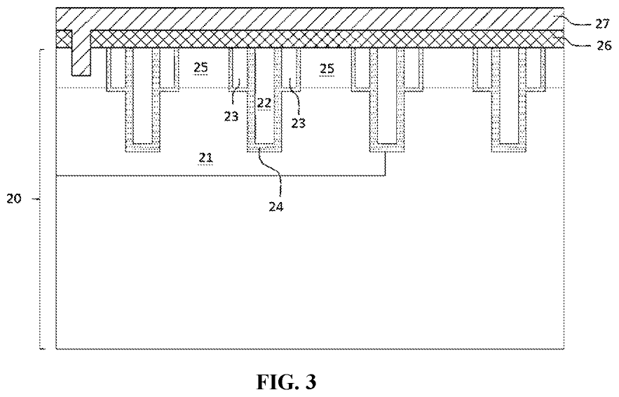

FIG. 3 is a cross-sectional view of a terminal structure of a semiconductor power device according to a third embodiment of the present application. As shown in FIG. 3, a terminal structure of a semiconductor power device in the embodiment of the present application includes four grooves 40, the depth of the first p-type doped region 21 is greater than the depths of the grooves 40, and in this case, the first p-type doped region 21 covers only a portion of the grooves 40.

The terminal structure of the semiconductor power device of the present application can adjust the longitudinal electric field distribution near the groove such that the electric field distribution in the first p-type doped region is concentrated at the bottom position of the upper groove portion and at the bottom position of the lower groove portion. In this manner, the electric field at the bottom of the groove (that is, at the bottom position of the lower groove portion) can be reduced, and the withstand voltage of the semiconductor power device can be improved. For example, when all the grooves are covered and surrounded by the first p-type doped region, the electric field distribution in the first p-type doped region can be adjusted. In one embodiment, when a thick oxide layer is used between the second electrode and the n-type epitaxial layer, a capacitor with the thick oxide layer can fix movable charges in a terminal of the semiconductor power device and improve the reliability of the semiconductor power device. Moreover, a thin oxide layer between the first electrode and the n-type epitaxial layer can alleviate the problem of unbalanced stress on the surface of n-type epitaxial layer between the terminal of the semiconductor power device and an active region caused by grooves.

The above embodiments are support for the technical idea of the terminal structure of the semiconductor power device provided in the present application, and cannot thereby limit the scope of the present application.

What is claimed is:

1. A terminal structure of a semiconductor power device, comprising:
an n-type epitaxial layer;
at least one groove disposed in the n-type epitaxial layer, wherein the at least one groove each comprises an upper groove portion and a lower groove portion;
a first electrode disposed in the upper groove portion and a second electrode disposed at least in the lower groove portion, wherein every two among the second electrode, the first electrode, and the n-type epitaxial layer are isolated by an insulating dielectric layer; and
a first p-type doped region adjacent to the at least one groove.

2. The terminal structure of the semiconductor power device of claim 1, wherein the first p-type doped region is externally connected to a source voltage.

3. The terminal structure of the semiconductor power device of claim 1, wherein a depth of the first p-type doped region is greater than a depth of the at least one groove, and the first p-type doped region covers and surrounds all or part of the at least one groove.

4. The terminal structure of the semiconductor power device of claim 1, wherein a thickness of an insulating dielectric layer between the second electrode and the n-type epitaxial layer is greater than or equal to a thickness of an insulating dielectric layer between the first electrode and the n-type epitaxial layer.

5. The terminal structure of the semiconductor power device of claim 1, further comprising a second p-type doped region disposed in the first p-type doped region, wherein a doping concentration of the second p-type doped region is greater than a doping concentration of the first p-type doped region.

6. The terminal structure of the semiconductor power device of claim 1, wherein a width of the upper groove portion is greater than a width of the lower groove portion.

7. The terminal structure of the semiconductor power device of claim 1, wherein the second electrode extends upwardly into the upper groove portion.

8. The terminal structure of the semiconductor power device of claim 7, wherein the second electrode is configured to divide the first electrode into two parts in the upper groove portion.

9. The terminal structure of the semiconductor power device of claim 1, further comprising an insulating layer covering the at least one groove and a metal layer covering the insulating layer.

10. The terminal structure of the semiconductor power device of claim 9, wherein the metal layer is externally connected to a source voltage.
